(19) United States
(12) Patent Application Publication
(10) Pub. No.: US 2014/0159777 A1
(43) Pub. Date: Jun. 12, 2014

(54) VOLTAGE DETECTOR AND SEMICONDUCTOR DEVICE INCLUDING THE SAME

(71) Applicant: SK hynix Inc., Gyeonggi-do (KR)

(72) Inventor: Jin-Yong SEONG, Seoul (KR)

(73) Assignee: SK hynix Inc., Gyeonggi-do (KR)

(21) Appl. No.: 14/093,352

(22) Filed: Nov. 29, 2013

(30) Foreign Application Priority Data
Dec. 7, 2012 (KR) 10-2012-0141728

(51) Int. Cl. H03K 17/30

(52) U.S. Cl. CPC H03K 17/302
USPC 327/109; 324/76.11

(57) ABSTRACT

Provided are a voltage detector that blocks out an input signal for an electronic device when a level of an input voltage for determining a voltage level of the input signal is equal to or less than a predetermined level and a semiconductor device including the same. The voltage detector outputs a detection signal indicating whether or not a level of a first voltage exceeds a first threshold, using the first voltage and a second voltage, which is independent of the first voltage.

### CROSS-REFERENCE TO RELATED APPLICATIONS

The present application claims priority of Korean Patent Application 10-2012-0141728, filed on Dec. 7, 2012, which is incorporated herein by reference in its entirety.

### BACKGROUND

1. Field

Exemplary embodiments of the present invention relate to a voltage detector and a semiconductor device including the same, and more particularly, to a voltage detector capable of blocking out an input signal for an electronic device according to a level of an input voltage and a semiconductor device including the same.

2. Description of the Related Art

Recently, a device uses a plurality of independent voltages such as an input voltage for determining a voltage level of an input signal for an electronic device and an internal voltage for driving an internal element of the electronic device.

An electronic device such as a mobile device, to which power consumption is one of main concerns, frequently turns power on and off according to whether or not it needs power for operation.

In such electronic device, an input signal may have an unintended level due to an insufficient level of an input voltage in spite of a normal supply of an internal voltage. As a result, the internal element of the electronic device may malfunction due to the unintended level of the input signal.

### SUMMARY

Various embodiments are directed to a voltage detector that may block out an input signal for an electronic device when a level of an input voltage for determining a voltage level of the input signal is equal to or less than a predetermined level and to a semiconductor device including the same.

In an embodiment, a voltage detector may output a detection signal indicating whether or not a level of a first voltage exceeds a first threshold, using the first voltage and a second voltage independent of the first voltage.

The voltage detector may include a voltage division unit including two or more resistive elements, resistance values of which are determined according to the voltage level of the first voltage, and suitable for dividing a level of the second voltage.

The resistive elements may block a current path between the second voltage and a ground voltage when the level of the first voltage is less than a second threshold or exceeds a third threshold. The first threshold may be greater than the second threshold and may be less than the third threshold.

The voltage division unit may further include resistors connected to the resistive elements.

The voltage division unit may further include a diode suitable for lowering the level of the second voltage.

The voltage detector may further include a buffer suitable for generating the detection signal based on the second voltage, the level of which is divided by the voltage division unit.

In an embodiment, a semiconductor device may include an input block driven by a first voltage and suitable for determining a voltage level of an external signal and outputting the external signal, the voltage level of which is determined, as an input signal, a voltage detector suitable for outputting a detection signal indicating whether or not a level of the first voltage exceeds a first threshold and a gate block suitable for generating an output signal based on the input signal in response to the detection signal.

The gate block may generate the output signal, a voltage level of which is a second voltage, when the level of the first voltage is less than the first threshold.

The gate block may shift the voltage level of the input signal to a level of the second voltage, when the level of the first voltage exceeds the first threshold.

### BRIEF DESCRIPTION OF THE DRAWINGS

FIG. 1 is a circuit diagram illustrating a voltage detector in accordance with an embodiment of the present invention.

FIG. 2 is a block diagram illustrating a semiconductor device in accordance with an embodiment of the present invention.

FIG. 3 is a circuit diagram illustrating a gate unit shown in FIG. 2.

### DETAILED DESCRIPTION

Various embodiments will be described below in more detail with reference to the accompanying drawings. The present invention may however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, reference numerals correspond directly to the like numbered parts in the various figures and embodiments of the present invention. It is also noted that in this specification, “connected/coupled” refers to one component not only directly coupling another component but also indirectly coupling another component through an intermediate component. In addition, a singular form may include a plural form as long as it is not specifically mentioned in a sentence.

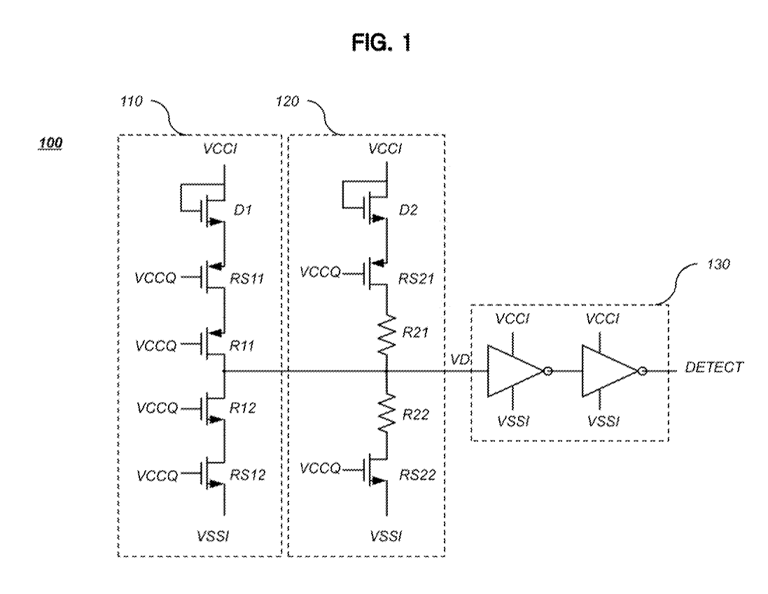

FIG. 1 is a circuit diagram illustrating a voltage detector in accordance with an embodiment of the present invention.

In the present embodiment, the voltage detector 100 in accordance with the embodiment of the present invention may detect whether or not a level of an input voltage VCCQ exceeds a first threshold. The input voltage VCCQ may determine a voltage level of an input signal.

The voltage detector 100 may include a first voltage division unit 110, a second voltage division unit 120, and a buffer 130.

In the present embodiment, the voltage detector 100 may include both of the first and second voltage division units 110 and 120. Further, in another embodiment, the voltage detector 100 may include only any one of the first and second voltage division units 110 and 120.

In the present embodiment, the first voltage division unit 110, the second voltage division unit 120, and the buffer 130 may be driven by the input voltage VCCQ and an internal voltage VCCI, which may be independent of each other and may have different levels to each other.

The internal voltage VCCI may be generated from an external voltage (not illustrated), which is independent of the input voltage VCCQ.

When supply of the internal voltage VCCI is cut off, no DC current paths are formed in the first voltage division unit 110 and the second voltage division unit 120. Thus, current consumption may be reduced. That is, when the internal voltage VCCI is not supplied, the voltage detector 100 does not operate.

The first voltage division unit 110 may include a first diode D1, first switching elements RS11 and RS12, and resistive elements R11 and R12. The first diode D1 may lower the voltage level of the internal voltage VCCI, and the first switching elements RS11 and RS12 and the resistive elements R11 and R12 may be turned on/off according to the input voltage VCCQ.

The first diode D1 may be implemented with an NMOS transistor configured to receive the internal voltage VCCI through a gate and source thereof. The first diode D1 may lower the voltage level of the internal voltage VCCI when the internal voltage VCCI has a higher level than the input voltage VCCQ.

The first switching elements RS11 and RS12 may be implemented with a PMOS transistor and an NMOS transistor respectively, which may receive the input voltage VCCQ through each gate thereof. The first switching elements RS11 and RS12 may block a current path between the internal voltage VCCI and a ground voltage VSSI when the level of the input voltage VCCQ is lower than a second threshold or higher than a third threshold, thereby preventing current consumption. In the present embodiment, the first threshold may be greater than the second threshold and less than the third threshold.

When the level of the input voltage VCCQ is between the second threshold and the third threshold, the first switching elements RS11 and RS12 may serve as resistive elements. The resistance values of the first switching elements RS11 and RS12 may be changed according to the level of the input voltage VCCQ.

The resistive elements R11 and R12 may be implemented with an NMOS transistor and a PMOS transistor, respectively, which receive the input voltage VCCQ through each gate thereof. Resistance ratios of the resistive elements R11 and R12 may be controlled by adjusting physical structure of the MOS transistors such as channel widths and channel lengths.

The second voltage division unit 120 may include a second diode D2, second switching elements RS21 and RS22, and resistors R21 and R22. The second voltage division unit 120 may have substantially the same configuration as the first voltage division unit 110 except that the resistors R21 and R22 are included in the second voltage division unit 120 instead of the resistive elements R11 and R12 included in the first voltage division unit 110. The second diode D2 and the second switching elements RS21 and RS22 may correspond to the first diode D1 and the first switching elements RS11 and RS12, respectively.

In the present embodiment, the buffer 130 may include two inverters connected in series.

In the present embodiment, the first and second diodes D1 and D2 the first and second switches RS11, RS12, RS21, and RS22, and the resistors and resistive elements R11, R12, R21, and R22, which are included in the first and second voltage division units 110 and 120 and are connected in series and in parallel, may divide the internal voltage VCCI and output a divided voltage VD.

The voltage detector 100 in accordance with the present embodiment may output a detection signal DETECT, The detection signal DETECT may have a high level when the level of the input voltage VCCQ is equal to or less than the first threshold and may have a low level when the voltage level of the input voltage VCCQ exceeds the first threshold. When the level of the input voltage VCCQ is equal to or less than the first threshold, the input voltage VCCQ may not have a sufficient level to determine a sufficient voltage level of the input signal IN, When the voltage level of the input voltage VCCQ exceeds the first threshold, the input voltage VCCQ may have a sufficient level to determine a sufficient voltage level of the input signal IN.

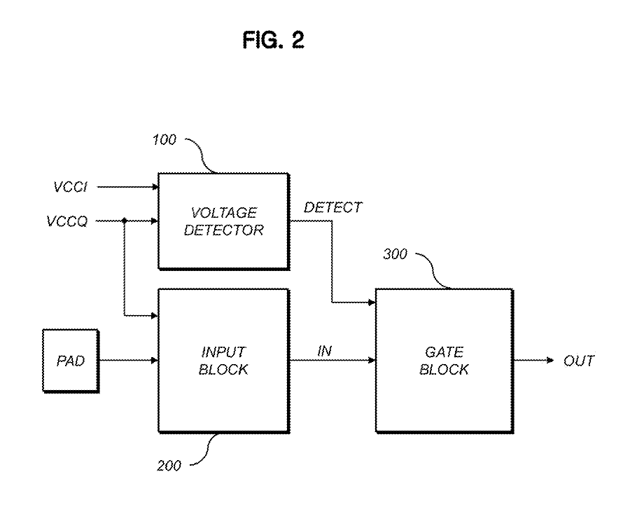

FIG. 2 is a block diagram illustrating a semiconductor device in accordance with an embodiment of the present invention.

The semiconductor device in accordance with the embodiment of the present invention may receive an input signal IN and output an output signal OUT that serve as an input signal for an electronic device (not illustrated). The semiconductor device in accordance with the embodiment of the present invention may output the output signal OUT that may be related or may not be related to the input signal IN according to the detection signal DETECT from the voltage detector 100 and indicating whether or not the level of the input voltage VCCQ exceeds the first threshold.

The semiconductor device in accordance with the embodiment of the present invention may include the voltage detector 100 shown in FIG. 1, an input block 200, and a gate block 300.

As described above, the voltage detector 100 may output the detection signal DETECT indicating whether or not the level of the input voltage VCCQ exceeds the first threshold or the input voltage VCCQ has a sufficient level to determine a sufficient voltage level of the input signal IN. The detection signal DETECT may have a high level when the level of the input voltage VCCQ is equal to or less than the first threshold, which may mean that the input voltage VCCQ does not have a sufficient level to determine a sufficient voltage level of the input signal IN, and may have a low level when the voltage level of the input voltage VCCQ exceeds the first threshold, which may mean that the input voltage VCCQ has a sufficient level to determine a sufficient voltage level of the input signal IN.

The voltage detector 100 included in the semiconductor device in accordance with the embodiment of the present invention may detects the level of the input voltage VCCQ using the internal voltage VCCI, as described above with reference to FIG. 1.

The input block 200 may receive a signal from an external through a pad and output the input signal IN, which may have a high or low level according to the input voltage VCCQ that may be input to the input block 200. For this operation, the input block 200 may include a buffer (not illustrated) driven by the input voltage VCCQ.

The gate block 300 may generate an output signal OUT based on the input signal IN outputted from the input block 200.

More specifically, the gate block 300 may generate the output signal OUT, which is related to the input signal IN, when the detection signal DETECT outputted from the voltage detector 100 has a low level or the input voltage VCCQ has a sufficient level to determine a sufficient voltage level of the input signal IN. When the detection to signal DETECT outputted from the voltage detector 100 has a high level or the input voltage VCCQ does not have a sufficient level to determine a sufficient voltage level of the input signal IN, the gate block 300 may generate an output signal OUT that is not related to the input signal IN. The output signal OUT may serve as an input signal for an electronic device (not illustrated). In the present embodiment, when the detection signal DETECT has a high level, the gate block 300 may generate the output signal OUT having a level with which the electronic device receiving the output signal OUT as an input may prevent malfunction.

Thus, it is possible to prevent the malfunction of the electronic device using the output signal OUT as an input despite the input signal IN does not have a sufficient voltage level because the level of the input voltage VCCQ is equal to or less than the first threshold.

The gate block 300 may generate the output signal OUT based on the input signal IN when the detection signal DETECT has a low level or the voltage level of the input voltage VCCQ exceeds the first threshold, which may mean that the input voltage VCCQ has a sufficient level to determine a sufficient voltage level of the input signal IN.

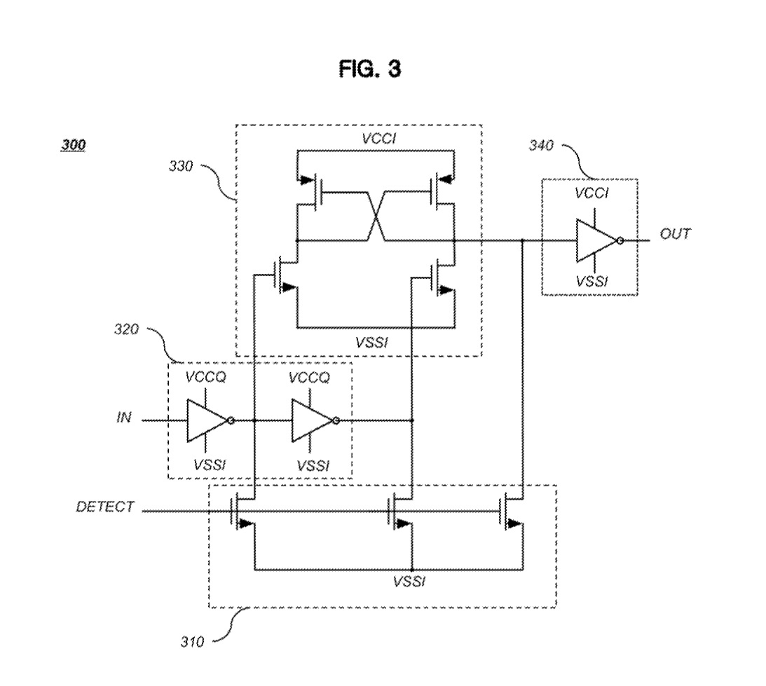

FIG. 3 is a circuit diagram illustrating the gate block 300 shown in FIG. 2.

The gate block 300 in accordance with the present embodiment may include a detection control unit 310, a signal input unit 320, a level conversion unit 330, and a buffer 340.

When the detection signal DETECT has a high level, that is, when the voltage level of the input voltage VCCQ is less than the first threshold, the detection control unit 310 may turn off the level conversion unit 330. Simultaneously, the detection control unit 310 may input a low-level signal to the buffer 340. The buffer 340 may output the output signal OUT having a high level signal based on the received low-level signal. The output signal OUT outputted from the buffer 340 may have a level of the internal voltage VCCI.

When the detection signal DETECT has a low level that when the voltage level of the input voltage VCCQ exceeds the first threshold, the detection control unit 310 is deactivated. Thus, the level conversion unit 330 may receive the input signal IN having a level of the input voltage VCCQ through the signal input unit 320 for amplifying the input signal IN to have the level of the input voltage VCCQ, convert the received input signal IN into a signal having a level of the internal voltage VCCI and output the converted signal as the output signal OUT through the buffer 340.

FIG. 3 illustrates the embodiment in which the gate block 300 may serve as a level shifter, However, the gate block in accordance with the embodiment of the present invention is not limited thereto.

In accordance with the embodiments of the present invention, when a level of the input voltage is equal to or less than a predetermined level, an input signal having insufficient voltage level due to the insufficient level of the input voltage may be blocked out for an electronic device using the input signal to prevent a malfunction of the electronic device. Furthermore, when a voltage for internal operation is not supplied or the level of the input voltage is very low or sufficiently high, for example the level of the input voltage VCCQ is lower than the second threshold or higher than the third threshold as described above, the DC current path of the voltage detector may be blocked to prevent current consumption of the voltage detector.

Although various embodiments have been described for illustrative purposes, it will be apparent to those skilled in the art that. various changes and modifications may be made without departing from the spirit and scope of the invention as defined in the following claims.

What is claimed:

1. A voltage detector suitable for outputting a detection signal indicating whether or not a level of a first voltage exceeds a first threshold, using the first voltage and a second voltage, which is independent of the first voltage.

2. The voltage detector of claim 1, comprising a voltage division unit comprising two or more resistive elements, resistances values of which are determined according to the level of the first voltage, and suitable for dividing a level of the second voltage.

3. The voltage detector of claim 2, wherein the resistive elements block a current path between the second voltage and a ground voltage when the level of the first voltage is less than a second threshold or exceeds a third threshold, and
wherein the first threshold is greater than the second threshold and is less than the third threshold.

4. The voltage detector of claim 3, wherein the voltage division unit further comprises resistors connected to the resistive elements.

5. The voltage detector of claim 3 wherein the voltage division unit further comprises a diode suitable for lowering the level of the second voltage.

6. The voltage detector of claim 2, further comprising a buffer suitable for generating the detection signal based on the second voltage, the level of which is divided by the voltage division unit.

7. A semiconductor device comprising:
an input block driven by a first voltage and suitable for determining a voltage level of an external signal and outputting the external signal, the voltage level of which is determined, as an input signal;
a voltage detector suitable for outputting a detection signal indicating whether or not a level of the first voltage exceeds a first threshold; and
a gate block suitable for generating an output signal based on the input signal in response to the detection signal.

8. The semiconductor device of claim wherein the voltage detector comprises a voltage d vision unit comprising two or more resistive elements, resistance values of which are set according to the level of the first voltage, and suitable for dividing a level of a second voltage independent of the first voltage.

9. The semiconductor device of claim 8, wherein the resistive elements block a current path between the second voltage and a ground voltage when the level of the first voltage is less than a second threshold or exceeds a third threshold, and
wherein the first threshold is greater than the second threshold and is less than the third threshold.

10. The semiconductor device of claim 9, wherein the voltage division unit further comprises resistors connected to the plurality of resistive elements.

11. The semiconductor device of claim 9, wherein the voltage division unit further comprises a diode suitable for lowering the level of the second voltage.

12. The semiconductor device of claim 8, wherein the voltage detector further comprises a buffer suitable for generating the detection signal based on the second voltage, the level of which is divided by the voltage division unit.

13. The semiconductor device of claim 7, wherein the gate block generates the output signal, a voltage level of which is a second voltage, when the level of the first voltage is less than the first threshold.

14. The semiconductor device of claim 13, wherein the gate block shifts the voltage level of the input signal to a level of the second voltage, when the level of the first voltage exceeds the first threshold.
